(19) United States
(12) Patent Application Publication
(10) Pub. No.: US 2006/0076612 A1
(43) Pub. Date: Apr. 13, 2006

(54) Semiconductor device and manufacturing method of the same

(76) Inventors: Seiji Otake, Saitama (JP); Takashi Ogura, Gunma (JP)

Correspondence Address: FISH & RICHARDSON P.C., P.O. BOX 1022, MINNEAPOLIS, MN, 55440-1022, US

(21) Appl. No.: 11/241,272

(22) Filed: Sep. 29, 2005

(30) Foreign Application Priority Data
Sep. 30, 2004 (JP) 2004-285689
Sep. 16, 2005 (JP) 2005-269874

(51) Int. Cl. H01L 29/792

(52) U.S. Cl. 257/324

(57) ABSTRACT

In a manufacturing method of a semiconductor device according to the invention, a silicon oxide film, a polysilicon film, and silicon nitride film are deposited. An opening for forming a LOCOS oxide film is provided in the polysilicon film and the silicon nitride film. Then, using the opening, a P-type diffusion layer is formed by implanting ions by a self-alignment technique. Afterward, the LOCOS oxide film is formed on the opening. According to this manufacturing method, it becomes possible to form, with high alignment accuracy, the P-type diffusion layer used as a drain region in an off-set region.

Priority is claimed to Japanese Patent Application Numbers JP2004-285689, filed on Sep. 30, 2004, and JP2005-269874, filed on Sep. 16, 2005, the disclosures of which are incorporated herein by reference in its entireties.

### BACKGROUND OF THE INVENTION

1. Field of the Invention

The present invention relates to a technology of forming a drain region in an off-set region in order to realize a reduction of an on-resistance value.

2. Description of the Related Art

In conventional manufacturing methods of a semiconductor device, there is a manufacturing method where: a P-type silicon substrate is prepared, and an ion-implantation mask for forming an off-set drain region is formed on a surface of the substrate; after ions of an impurity is implanted with desired conditions, the ion-implantation mask is removed; then, the impurity is diffused with a thermal treatment process, whereby an off-set drain region is formed; afterward, an oxide film and a silicon nitride film for forming a field oxide film are laminated on the surface of the substrate; then, the silicon nitride film is patterned in order that an opening used in forming the field oxide film can be formed; and the oxide film and the silicon nitride film are removed after the field oxide film is formed by use of a thermal oxidation method. This technology is described for instance in pp. 5-6, and FIGS. 3 to 7 in Japanese Patent Application Publication No. 2003-204062.

In the conventional manufacturing methods of a semiconductor device, there is another manufacturing method where: in a drain region formed with a double diffusion structure, first, a LOCOS (Local Oxidation of Silicon) oxide film is formed; at this time, a bird's beak shape of the LOCOS oxide film on its side facing toward the drain region is formed with a slow slope and to be large; then, by utilizing the bird's beak shape of the LOCOS oxide film, ions of an impurity are implanted through a top surface of the LOCOS oxide film, at a high acceleration voltage, and is diffused; according to this manufacturing method, a deeply-diffused low-concentration diffusion layer of the drain region is formed; and, after the above processes, a high-concentration diffusion layer of the drain region is formed by implanting ions of an impurity, by use of a self-alignment technique by using the LOCOS oxide film, through the low-concentration diffusion layer. This technology is described for instance in pp. 8-10, and FIGS. 5 to 9 in Japanese Patent Application Publication No. 2003-309258.

As described above, in one conventional manufacturing method of a semiconductor device, an ion-implantation mask for forming an off-set drain region is formed. After the off-set drain region is formed, the ion-implantation mask is removed, and an oxide film and a silicon nitride film for forming a field oxide film are laminated. Then, after the silicon nitride film is patterned and the field oxide film is formed, the oxide film and the silicon nitride film are removed. According to this manufacturing method, a mask used in forming the off-set drain region, and a mask for forming the field oxide film, are respectively formed. Accordingly, due to occurrences of mask displacement in the respective processes, alignment accuracy for aligning the off-set drain region and the field oxide film becomes low. Furthermore, there is a problem that it is difficult to realize a desired breakdown voltage characteristic and a desired on-resistance value.

Additionally, a mask used in formatting the off-set drain region, and a mask for forming the field oxide film are respectively formed as different masks. According to this manufacturing method, there arises a problem that a manufacturing cost is high because the number of masks and the number of manufacturing processes increase.

In another conventional manufacturing method of a semiconductor device, an oxide film and a silicon nitride film for forming a LOCOS oxide film on a surface of an epitaxial layer are formed. The oxide film and the silicon nitride film in a region where the LOCOS oxide film is to be formed are selectively formed. Then, after the LOCOS oxide film is formed, a drain region is formed by ion implantation through a top surface of the bird's beak shape of the LOCOS oxide film. Accordingly, there is a problem that displacement occurs with respect to a formation region of the drain region due to mask displacement in forming the LOCOS oxide film, a film thickness and a shape of a bird's beak portion, and the like, whereby alignment accuracy for the drain region is low.

Additionally, if the drain region is formed in a manner that it reaches the vicinity of a back gate region formed in an overlapping manner with a source region, there arises a problem that a breakdown voltage is deteriorated. On the other hand, if the drain region is formed in a manner that it is far from the back gate region, there arises another problem that an on-resistance value is increased. That is, it is needed that a drain region be formed with high accuracy with a breakdown voltage, an on-resistance value, and the like taken into consideration. However, as described above, due to low accuracy in alignment of the drain region, there has been a problem that it is difficult to realize a desired breakdown voltage characteristic and a desired on-resistance value.

### SUMMARY OF THE INVENTION

The present invention provides a manufacturing method of a semiconductor device. The method includes a process of forming, after forming a first drain diffusion layer through a surface of a semiconductor layer, an insulating film on the surface of the semiconductor layer, and then selectively removing the insulating film in order that an opening can be provided in a region of the semiconductor layer where a field oxide film is intended to be formed, a process of forming the field oxide film on the semiconductor layer after forming a second drain diffusion layer from a surface of the first drain diffusion layer by use of a self-alignment technique by using the opening, and a process of forming a gate electrode on the upper surface of the semiconductor layer after partially removing the insulating film, and then forming a back gate diffusion layer and a source diffusion layer in the semiconductor layer below the gate electrode. Consequently, according to the invention, a second drain diffusion layer is formed by a self-alignment technique, using the insulating layer patterned for forming the field oxide film. According to this manufacturing method, it becomes possible to form the second drain diffusion layer in the off-set region with high alignment accuracy.

The present invention also provides the manufacturing method that includes in the process of forming the back gate diffusion layer, the back gate diffusion layer is formed by a self-alignment technique, using the gate electrode formed by utilizing, as an alignment mark, a step height on the field oxide film. Consequently, according to this invention, the back gate diffusion layer is formed by a self-alignment technique, using the gate electrode. According to this manufacturing method, it becomes possible to arrange the second drain diffusion layer and the back gate diffusion layer with high alignment accuracy and thereby to realize a desired breakdown voltage characteristic and a desired on-resistance value.

The present invention further provides the manufacturing method that includes, in the process of selectively removing the insulating film, after a gate oxide film, a first silicon film, and a silicon nitride film are sequentially deposited, the first silicon film and the silicon nitride film are removed in a manner that a portion thus removed corresponds to a region where the field oxide film is to be formed. Consequently, according to this invention, the gate oxide film, and the first silicon film used as a gate electrode is used as a mask used in forming the field oxide film. According to this manufacturing method, it becomes possible to simplify manufacturing processes and thereby to reduce a manufacturing cost.

The present invention further provides the manufacturing method that includes, in the process of partially removing the insulating film, the silicon nitride film is removed after the field oxide film is formed. Consequently, according to this invention, the field oxide film is formed in a state where a gate oxide film is covered with a silicon film. Then, a gate electrode is formed of the silicon film. According to this manufacturing method, it becomes possible to prevent a gate oxide film, which is deposited before forming the field oxide film, from growing to exceed a desired thickness.

The present invention further provides the manufacturing method that includes, in the process of forming the gate electrode, after the silicon nitride film is removed, a second silicon film is deposited on the upper surface of the semiconductor layer, and a step height on the field oxide film is utilized as an alignment mark. Consequently, according to this invention, it becomes possible to form the gate electrode with high alignment accuracy with respect to the second drain diffusion layer. Furthermore, it becomes possible to form a back gate diffusion layer with high alignment accuracy with respect to the second drain diffusion layer, the back gate diffusion layer being formed by a self-alignment technique, using the gate electrode.

The present invention further provides a semiconductor device that includes a semiconductor layer, a field oxide film, a gate electrode; a gate oxide film, a first drain diffusion layer of one conductivity type, a second drain diffusion layer of the one conductivity type, a back gate diffusion layer of another conductivity type (hereinbelow, referred to as an opposite conductivity type), whose conductivity is opposite to the one conductivity type; and a source diffusion layer of the one conductivity type. The invention also provides the semiconductor device that includes the field oxide film is formed in a surface of the semiconductor layer, the gate electrode is formed in a manner that one end thereof can be on the gate oxide film formed on the semiconductor layer, the gate oxide film is sandwiched between the gate electrode and the semiconductor layer surface, the other end of the gate electrode is formed on one end of the field oxide film; the first drain diffusion layer is formed in a region facing the other end of the field oxide film, the second drain diffusion layer is formed in order that it can overlap the first drain diffusion layer, the back gate diffusion layer is formed below the gate electrode, and the source diffusion layer is formed in a manner that it extends below the one end side of the gate electrode.

### BRIEF DESCRIPTION OF THE DRAWINGS

FIG. 1 is a cross-sectional view explaining a manufacturing method of a semiconductor device in an embodiment of the invention.

FIG. 2 is a cross-sectional view explaining the manufacturing method of a semiconductor device in the embodiment of the invention.

FIG. 3 is a cross-sectional view explaining the manufacturing method of a semiconductor device in the embodiment of the invention.

FIG. 4 is a cross-sectional view explaining the manufacturing method of a semiconductor device in the embodiment of the invention.

FIG. 5 is a cross-sectional view explaining the manufacturing method of a semiconductor device in the embodiment of the invention.

FIG. 6 is a cross-sectional view explaining the manufacturing method of a semiconductor device in the embodiment of the invention.

FIG. 7 is a cross-sectional view explaining the manufacturing method of a semiconductor device in the embodiment of the invention.

FIG. 8 is a cross-sectional view explaining the manufacturing method of a semiconductor device in the embodiment of the invention.

FIG. 9 is a cross-sectional view explaining the manufacturing method of a semiconductor device in the embodiment of the invention

### DESCRIPTION OF THE PREFERRED EMBODIMENT

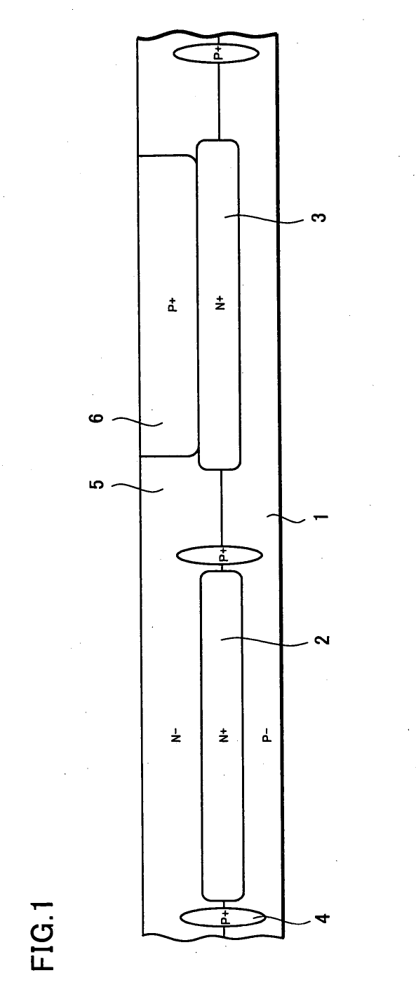

Hereinbelow, a manufacturing method of a semiconductor device, which is one embodiment of the invention, will be described in detail with respect to FIGS. 1 to 9.

FIGS. 1 to 9 are cross-sectional views for explaining the manufacturing method of a semiconductor device in this embodiment. Note that, the following descriptions will be given of a case where a P- and N-channel MOS transistors, for example, are formed in element formation regions defined by isolation regions. However, the embodiment of the invention is not necessarily limited to the case of this combination. For example, an applicable case may be a case where an NPN-type transistor, a vertical PNP transistor and the like may be formed in other device formation regions, and thereby a semiconductor integrated circuit device is formed.

First, as shown in FIG. 1, a P-type single crystal silicon substrate 1 is prepared. Through a surface of the substrate 1, by use of a publicly known photolithography technique, ions of an N-type impurity, which is for example phosphorus (P), are implanted to form N-type buried diffusion layers 2 and 3. Next, through the surface of the substrate 1, by use of a publicly known photolithography technique, ions of a P-type impurity, which is for example boron (B), are implanted to form a P-type buried diffusion layer 4. Afterward, the substrate 1 is placed on a susceptor of an epitaxial growth device.

Next, while a high temperature of around 1200° C., for example, is given to the substrate 1 by means of lump heating, SiHCl₃ gas and H₂ gas are introduced into a reaction tube. Thereby, an epitaxial layer 5 is grown to have a resistivity of 0.1 to 2.0 Ω·cm and a thickness of 0.5 to 1.5 μm. Then, through the surface of the epitaxial 5, by use of a publicly known photolithography technique, ions of a P-type impurity, which is for example boron (B), are implanted to form a P-type diffusion layer 6. The P-type diffusion layer 6 is diffused in a manner that it can partially overlap the N-type buried diffusion layer 3. Then, the P-type diffusion layer 6 is used as a drain region of a P-channel MOS transistor.

Note that the substrate 1 and the epitaxial layer 5 of this embodiment correspond to a “semiconductor layer” in the invention. Additionally, although shown in this embodiment is the case where the epitaxial layer 5 is formed as the only one epitaxial layer on the substrate 1, the invention is not necessarily limited to this case. For example, an applicable case may be a case where only a substrate corresponds to the “semiconductor layer” in the embodiment of the invention, or may be a case where a plurality of epitaxial layers are deposited on a surface of a substrate. Furthermore, the substrate may be an N-type single crystal silicon substrate, or may be a compound semiconductor substrate. Moreover, the P-type diffusion layer 6 of this embodiment corresponds to a “first drain diffusion layer” in the invention.

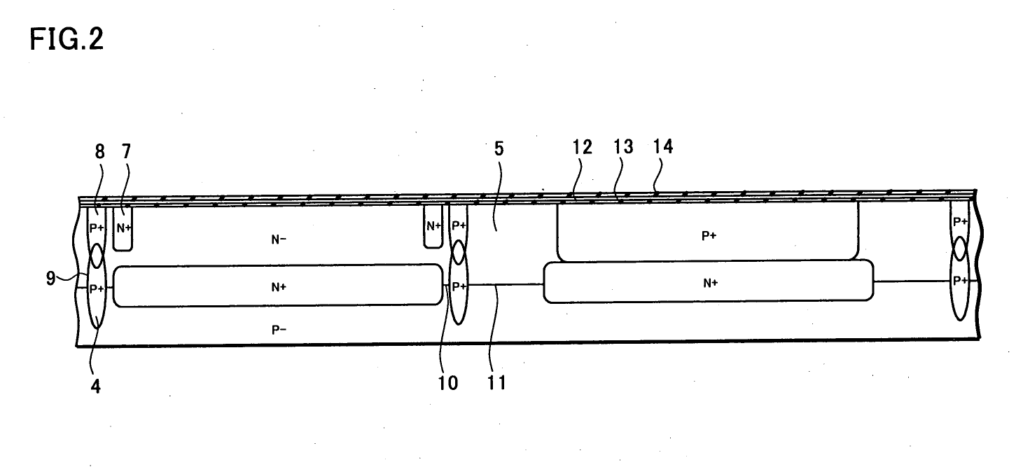

Next, as shown in FIG. 2, through the surface of the epitaxial layer 5, by use of a publicly known photolithography technique, ions of an N-type impurity, which is for example phosphorus (P), are implanted to form an N-type diffusion layer 7. Additionally, through the surface of the epitaxial layer 5, by use of a publicly known photolithography technique, ions of a P-type impurity, which is for example boron (B), are implanted to form a P-type diffusion layer 8. Then, an isolation region 9 is formed as a result of coupling of the P-type buried diffusion layer 4 and the P-type diffusion layer 8. As described above, by the isolation regions 9, the substrate 1 and the epitaxial layer 5 are divided into a plurality of element formation regions. In this embodiment, an N-channel MOS transistor is formed in a first element formation region 10, and a P-channel MOS transistor is formed in a second element formation region 11.

Afterward, on the surface of the epitaxial layer 5, a silicon oxide film 12 having a thickness of 150 to 350 Å, for example, is deposited. Then, over a top surface of the silicon oxide film 12, a polysilicon film 13 and a silicon nitride film 14 are sequentially deposited.

Note that the silicon oxide film 12, the polysilicon film 13 and the silicon nitride film 14 of this embodiment correspond to an “insulating layer” in the invention. Additionally, the polysilicon film 13 in this embodiment corresponds to a “first silicon film” in the invention. The “first silicon film” in the embodiment of the invention may be any film which forms a gate electrode.

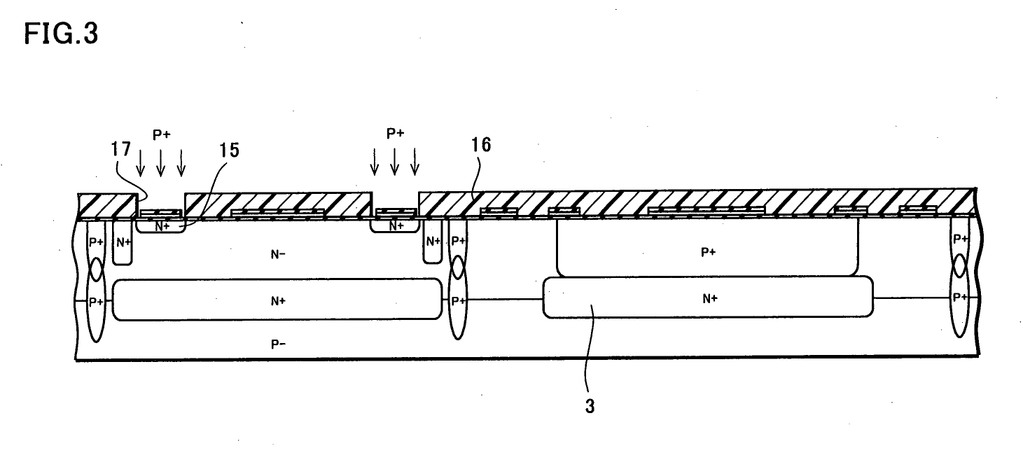

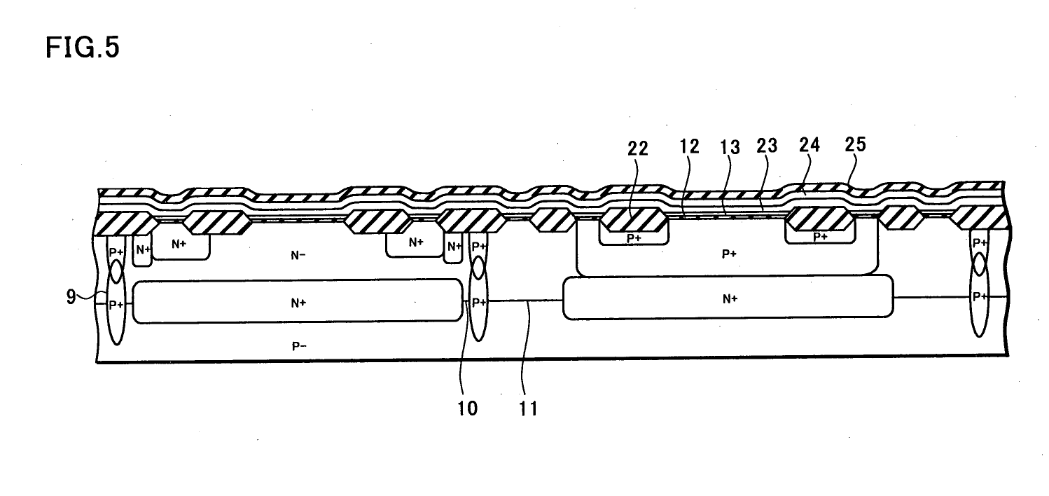

Next, as shown in FIG. 3, the polysilicon film 13 and the silicon nitride film 14 are selectively removed in order that an opening can be provided in a portion where a LOCOS oxide film 22 (refer to FIG. 5) is to be formed. At this time, although not illustrated, in a scribe line region, a step height is formed on the surface of the substrate 1 when the N-type buried diffusion layer 2 is formed. Then, by utilizing this step height as an alignment mark, the polysilicon film 13 and the silicon nitride film 14 are selectively removed.

Then, a photoresist 16 for forming an N-type diffusion layer 15, is formed on the surface of the epitaxial layer 5. Then, by use of a publicly known photolithography technique, an opening 17 is formed in the photoresist 16 on a top surface above a region where the N-type diffusion layer 15 is to be formed.

At this time, a step height of the polysilicon film 13 and the silicon nitride film 14, which are arranged on the surface of the epitaxial layer 5 can be utilized as an alignment mark. Then, by using the photoresist 16 as a mask, ions of an N-type impurity, which is for example phosphorus (P), are implanted to form the N-type diffusion layer 15. According to this manufacturing method, the N-type diffusion layer 15 can be shaped independently without being affected by a form of the LOCOS oxide film 22, the form, for example, being represented by a thickness of a bird's beak thereof, a form of the bird's beak and the like. Additionally, the N-type. diffusion layer 15 can be formed with high alignment accuracy with respect to the LOCOS oxide film 22.

Note that, although the LOCOS oxide film 22 of this embodiment corresponds to a “field oxide film” in the invention, the invention does not necessarily limit the field oxide film to be one obtained by use of a LOCOS method. The “field oxide film” in the embodiment of the invention may be one formed by use of a manufacturing method whereby a thick thermal oxide film can be formed.

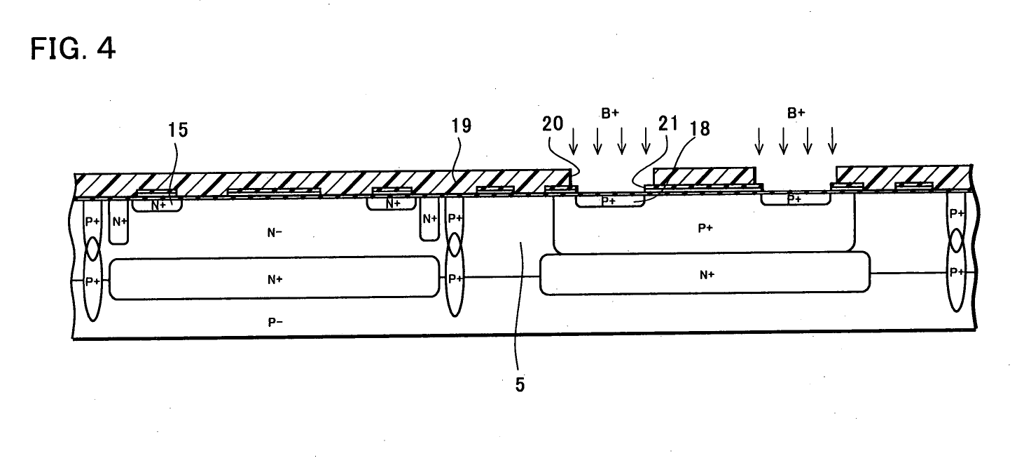

Next, as shown in FIG. 4, after the photoresist 16 is removed, a photoresist 19 for forming a P-type diffusion layer 18 is formed on the surface of the epitaxial layer 5. Then, by use of a publicly known photolithography technique, an opening 20 is formed in the photoresist 19 on a top surface of a region where the P-type diffusion layer 18 is to be formed. Then, by using the photoresist 19 as a mask, ions of a P-type impurity, which is for example boron (B), are implanted to form the P-type diffusion layer 18.

At this time, inside the opening 20 of the photoresist 19, an opening 21 common to the polysilicon film 13 and the silicon nitride film 14 is formed. Then, implanting ions by a self-alignment technique, using the opening 21, the P-type diffusion layer 18 can be formed with high alignment accuracy with respect to the LOCOS oxide film 22.

Note that the P-type diffusion layer 18 of this embodiment corresponds to a “second drain diffusion layer” in the invention.

Next, as shown in FIG. 5, by using the polysilicon film 13 and the silicon nitride film 14 as a mask, oxide film formation is performed onto the silicon oxide film 12 by means of steam oxidation at 800 to 1200° C., for example. At the same time, the LOCOS oxide film 22 is formed by applying a thermal treatment to the entire substrate 1. At this time, in a part of portions where the polysilicon film 13 and the silicon nitride film 14 are formed, a bird's beak is formed. Note that, a flat portion of the LOCOS oxide film 22 is formed to have a thickness of 3000 to 5000 Å, for example. In particular, on the isolation region, as a result of formation of the LOCOS oxide film 22, isolation between elements is more secured. Afterward, the silicon nitride film 14 is removed.

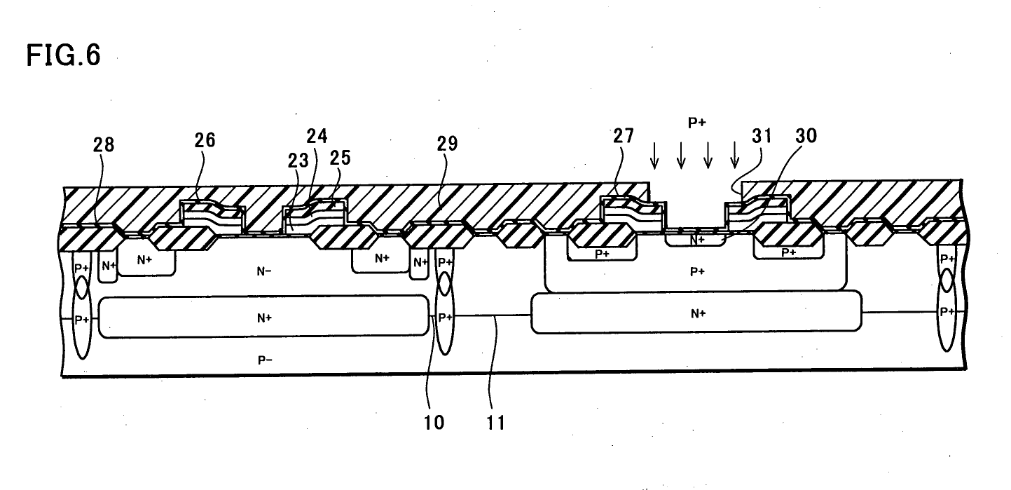

Next, over top surfaces of the polysilicon film 13 and the LOCOS oxide film 22, a polysilicon film 23, a tungsten silicon film 24 and a silicon oxide film 25 are sequentially deposited. At this time, in the first and second device formation regions 10 and 11, the silicon oxide film 12 remaining on the surface of the epitaxial layer 5 is used as a gate oxidation film. Additionally, over a top surface of the polysilicon film 13 remaining over a top surface of the silicon oxide film 12, the polysilicon film 23 and the tungsten silicon film 24 are further deposited. Furthermore, the polysilicon film 23 and the tungsten silicon film 24 are required to have desirable thicknesses because they are used as gate electrodes 26 and 27 (refer to FIG. 6). Note that the polysilicon 23 and the tungsten silicon film 24 of this embodiment correspond to a “second silicon film” in the invention. Moreover, the “second silicon film” in the embodiment of the invention may be any film which forms a gate electrode.

At this time, as described above by using FIG. 2, the polysilicon film 13 is deposited after the silicon oxide film 12 is deposited. Then, the silicon oxide film 12 is kept being covered with the polysilicon film 13 during a period after the LOCOS oxide film 22 is formed and before the polysilicon-film 23 is deposited thereon. According to this manufacturing method, the silicon oxide film 12 is oxidized, and hence an amount of its growth can be greatly reduced. Thereby, thicknesses of gate oxide films respectively of the N- and P-channel MOS transistors are maintained within adequate ranges.

Additionally, the silicon oxide film 12 used as a gate oxide film, and the polysilicon film 13 used as the gate electrodes 26 and 27 are used as a mask in forming the LOCOS oxide film 22. According to this manufacturing method, it becomes possible to eliminate processes of stacking and removing a silicon oxide film for forming the LOCOS oxide film 22, and hence it becomes possible to simplify manufacturing process and thereby to reduce a manufacturing cost.

Note that, in this embodiment, the polysilicon films 13 and 23 are formed in two depositing processes in order that they can be formed in desired thicknesses. According to this manufacturing method, a film thickness of the polysilicon film 13 can, be made thin. Therefore, it facilitates patterning at the time of forming the LOCOS oxide film 22. However, in this embodiment, another applicable case may be a case where a polysilicon film adequate for a film thickness of the gate electrodes 26 and 27 is formed in one depositing process. Note that the polysilicon film 13 and the polysilicon film 23 are integrally illustrated in FIGS. 6 to 9.

Next, as shown in FIG. 6, in the first and second element formation regions 10 and 11, the polysilicon film 23, the tungsten silicon film 24 and the silicon oxide film 25 are selectively removed. Then, the gate electrodes 26 and 27 are formed. At this point of time, step heights on the LOCOS oxide film 22, which have been already arranged on the epitaxial layer 5, are utilized as alignment marks. According to this manufacturing method, in both the first and second device formation regions 10 and 11, it becomes possible to form the respective gate electrodes 26 and 27 with high alignment accuracy with respect to the LOCOS oxide film 22.

Next, a TEOS film 28 is deposited over a top surface of the epitaxial layer 5, and a photoresist 29 is deposited over a top surface of the TEOS film 28. By using a publicly known photolithography technique, an opening 31 is formed in a region of the photoresist 29 where an N-type diffusion layer 30 is to be formed. Then by using the photoresist 29 as a mask, ions of an N-type impurity, which is for example phosphorus (P), are implanted to form an N-type diffusion layer 30. As illustrated, using the gate electrode 27, the N-type diffusion layer 30 is formed by a self-alignment technique. The N-type diffusion layer 30 is to be used as a back gate region for the P-channel MOS transistor.

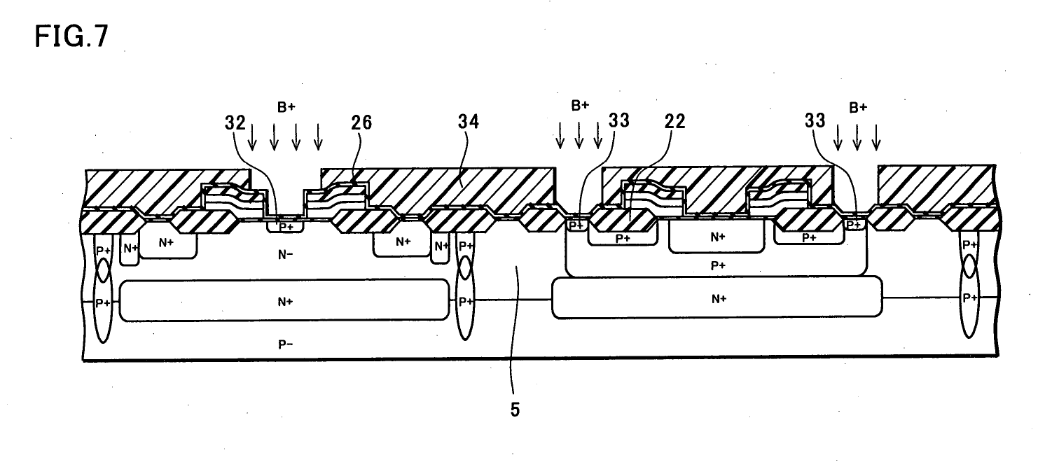

Next, as shown in FIG. 7, the photoresist 29 is removed, and then a photoresist 34 for forming P-type diffusion layers 32 and 33 is formed in the surface of the epitaxial layer 5. Then, by use of a publicly known photolithography technique, openings are formed in regions of the photoresist 34 where the P-type diffusion layers 32 and 33 are to be formed. Thereafter, by using the photoresist 34 as a mask, ions of a P-type impurity, which is for example boron (B), are implanted to form the P-type diffusion layers 32 and 33. At this time, as illustrated, using the gate electrode 26, the P-type diffusion layer 32 is formed by a self-alignment technique. On the other hand, using the LOCOS oxide film 22, the P-type diffusion layer 33 is formed by a self-alignment technique. Here, the P-type diffusion layer 32 is to be used as a back gate region for the N-channel MOS transistor. The P-type diffusion layer 33 is to be used as a drain region for the P-channel MOS transistor.

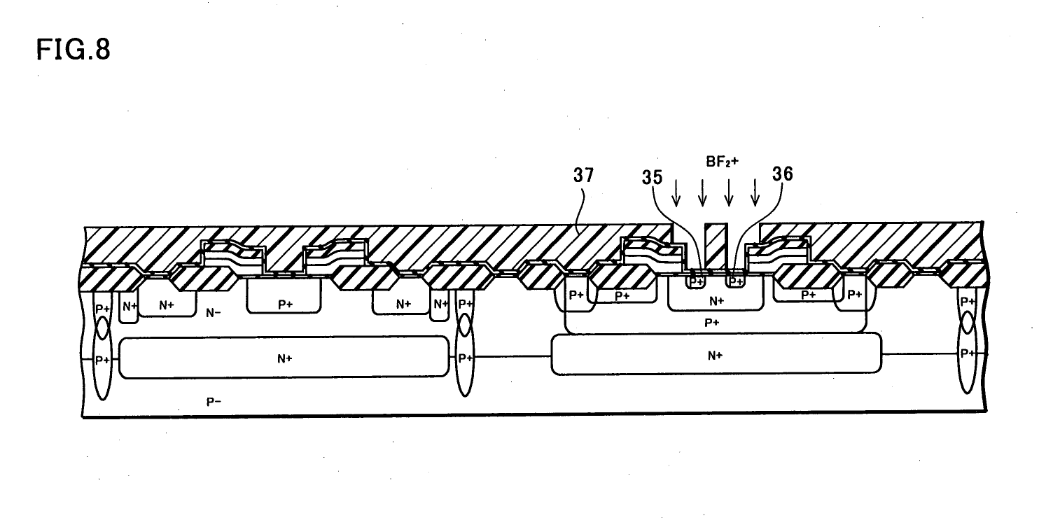

Next, as shown in FIG. 8, after the photoresist 34 is removed, a photoresist 37 for forming P-type diffusion layers 35 and 36 is formed in the surface of the epitaxial layer 5. Then, by using a publicly known photolithography technique, openings are formed in the photoresist 37 over top surfaces of regions where P-type diffusion layers 35 and 36 are to be formed. Thereafter, by using the photoresist 37 and the gate electrode 27 as a mask, ions of a P-type impurity, which is for example boron fluoride (BF₂), are implanted to form the P-type diffusion layers 35 and 36. The P-type diffusion layers 35 and 36 are used as source regions for the P-channel MOS transistor.

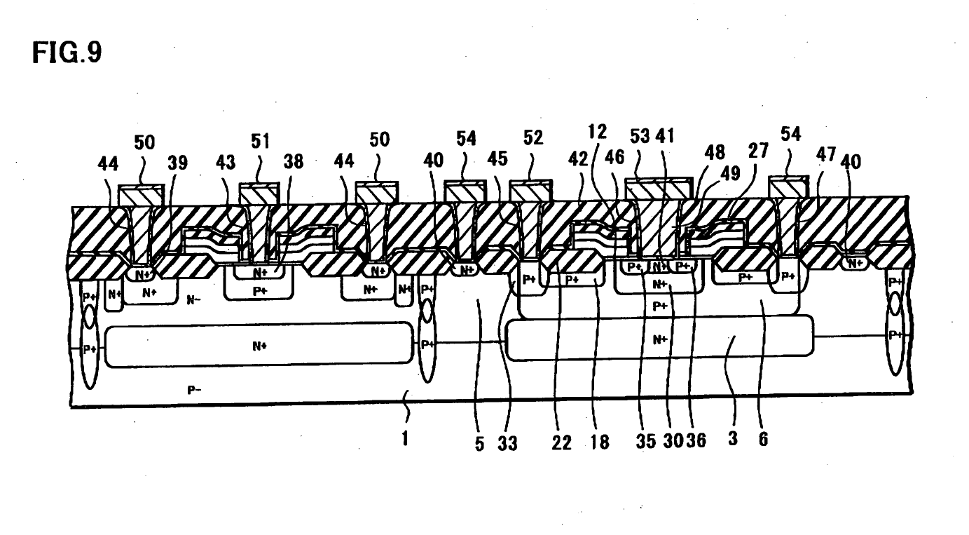

Next, as shown in FIG. 9, through the surface of the epitaxial layer 5, by using a publicly known photolithography technique, ions of an N-type impurity, which is for example phosphorus (P), are implanted to form N-type diffusion layers 38, 39, 40 and 41. The N-type diffusion layers 38 and 39 are used respectively as source and drain regions for the N-channel MOS transistor. A power supply potential is applied to the N-type diffusion layer 40, and the N-type diffusion layer 40 performs a function of inversion prevention with respect to the epitaxial layer 5 of P-channel MOS transistor. The N-type diffusion layer 41 is led to have the same potential as the P-type diffusion layers 35 and 36, and prevents a parasitic effect in the back gate regions of P-channel MOS transistor.

Afterward, over the top surface of the epitaxial layer 5, a BPSG (Boron Phospho Silicate Glass) film, an SOG (Spin On Glass) film and the like, for example, are deposited as an insulation layer 42. By applying dry-etching using, for example, CHF₃+O₂ gas, contact holes 43, 44, 45, 46, and 47 are formed in the insulation layer 42. A barrier metal film 48 is formed on inner walls of the contact holes 43, 44, 45, 46, and 47 and the like. Then, insides of the contact holes 43, 44, 45, 46, and 47 are filled with a tungsten (W) film 49. Over the top surface of the tungsten film 49, by use of a CVD method, an aluminum copper (AlCu) film, and a barrier metal film are deposited. Afterward, by using a publicly known photolithography technique, the aluminum copper film, and the barrier metal film are selectively removed. Thereafter, a drain electrode 50 and a source electrode 51 of the N-channel MOS transistor are formed. Additionally, a drain electrode 52 and a source electrode 53 of the P-channel MOS transistor are formed. Note that, although a wiring layer connected to the gate electrodes 26 and 27 is not illustrated in a cross-section shown in FIG. 9, the gate electrodes 26 and 27 are connected to a wiring layer in other region not illustrated in the drawing.

As described above, according to this embodiment, in the P-channel MOS transistor, the P-type diffusion layer 18 is formed of a mask used in forming the LOCOS oxide film 22. This means that in an off-set region of the P-channel MOS transistor, the P-type diffusion layer 18 can be formed with high alignment accuracy. According to this manufacturing method, an on-resistance value of the P-channel MOS transistor can be reduced. On the other hand, the P-type diffusion layer 18 of the drain region can be formed with high alignment accuracy with respect to the N-type diffusion layer 30 of the back gate region, and thus a breakdown voltage characteristic can be maintained.

Additionally, the drain regions of the P-channel MOS transistor are formed of the P-type diffusion layers 6, 18 and 33. Furthermore, below the contact hole 45, the P-type diffusion layers 6, 18 and 33 overlap one another, thus a state there becomes such that a concentration of the P-type impurity is high. On the other hand, the concentration of the P-type impurity becomes lower with decreasing distance to the N-type diffusion layer 30 of the back gate region. As a result of this concentration slope in the off-set region, an on-resistance value can be reduced while a breakdown voltage characteristic can be maintained.

Hereinbelow, a semiconductor device as an example according to the embodiment of the invention will be described in detail with reference to FIG. 9. As shown in FIG. 9, a P-channel MOS transistor is constituted of a P-type single crystal silicon substrate 1, an N-type buried diffusion layer 3, an N-type epitaxial layer 5, N-type diffusion layers 30 and 40 which are used as back gate regions, P-type diffusion layers 35 and 36 which are used as source regions, P-type diffusion layers 6, 18 and 33 which are used as drain regions, a LOCOS oxide film 22, a gate oxide film 12, and a gate electrode 27.

The N-type epitaxial layer 5 is formed to have, for example, a resistivity of 0.1 to 2.0 Ω·cm and a thickness of 0.5 to 1.5 μm. The P-type diffusion layer 6 is diffused in order that it can partially overlap the N-type buried diffusion layer 3. A flat-surface portion of the LOCOS oxide film 22 is formed to have a thickness of 3000 to 5000 Å, for example. The gate electrode 27 is formed in an order that one end thereof can be on a surface of the gate oxide film 12 which is formed on the epitaxial layer 5. The gate oxide film 12 is formed in a manner that it is sandwiched between the gate electrode 27 and the surface of the epitaxial layer 5. The gate electrode 27 is formed on one end of the LOCOS oxide film 22, and in order that the other end of the gate electrode 27 can be on the LOCOS oxide film 22. The P-type diffusion layer 33 is formed on the other end side of the LOCOS oxide film 22. The P-type diffusion layer 18 is formed below the formation region of the LOCOS oxide film 22. The N-type diffusion layers 30 and 41 used as a back gate diffusion layer is formed below the gate electrode 27. The P-type diffusion layers 35 and 36 used as a source gate diffusion layer are formed to extend below the one end side of gate electrode.

Note that various modifications are possible without departing from the scope of the embodiment of the invention.

According to the embodiment of the invention, a drain diffusion layer is formed in an off-set region by using an insulating layer, which is used as a mask for forming a field oxide film. According to this manufacturing method, it becomes possible to form the drain diffusion layer in an off-set region with high alignment accuracy. Thereby it becomes possible to realize a desired breakdown voltage characteristic and a desired on-resistance value.

Additionally, according to the embodiment of the invention, by utilizing a step height on the field oxide film, a gate electrode is patterned. By using a different end of the gate electrode, a back gate diffusion layer is formed by use of a self-alignment technique. According to this manufacturing method, it becomes possible to arrange a drain diffusion layer and the back gate diffusion layer with high alignment accuracy and thereby to realize a desired breakdown voltage characteristic and a desired on-resistance value.

Additionally, according to the embodiment of the invention, a gate oxide film, and a silicon film used as a gate electrode are used in forming the field oxide film. Afterward, a gate electrode is formed by using the gate oxide film and the silicon film. According to this manufacturing method, it becomes possible to simplify manufacturing processes and thereby to reduce a manufacturing cost.

Additionally, according to the embodiment of this invention, after a gate oxide film is deposited on the surface of a semiconductor layer, the gate oxide film is covered with a silicon film used as a gate electrode. Afterward, over a top surface of the silicon film, another silicon film is deposited in order that the gate electrode can have a desired thickness. According to this manufacturing method, it becomes possible to prevent a gate oxide film from growing excessively and to retain a film thickness of the gate oxide film at a desired thickness.

Furthermore, according to the embodiment of this invention, by forming the source diffusion layer to extend below the one end side of the gate electrode, it becomes less likely that current leakage occurs between a source and a drain of the device.

What is claimed is:

1. A manufacturing method of a semiconductor device, comprising the steps of:
forming, after forming a first drain diffusion layer through a surface of a semiconductor layer, an insulating film on the surface of the semiconductor layer, and then selectively removing the insulating film in order that an opening can be provided in a region of the semiconductor layer where a field oxide film is to be formed;
forming the field oxide film on the semiconductor layer after forming a second drain diffusion layer from a surface of the first drain diffusion layer by a self-alignment technique, using the opening; and
forming a gate electrode on the upper surface of the semiconductor layer after partially removing the insulating film, and then forming a back gate diffusion layer and a source diffusion layer in the semiconductor layer below the gate electrode.

2. The manufacturing method of a semiconductor device according to claim 1, wherein, in the step of forming the back gate diffusion layer, the back gate diffusion layer is formed by a self-alignment technique, using the gate electrode formed as an alignment mark, a step height on the field oxide film.

3. The manufacturing method of a semiconductor device according to claim 1, wherein, in the step of selectively removing the insulating film, after a gate oxide film, a first silicon film, and a silicon nitride film are sequentially deposited, the first silicon film and the silicon nitride film are removed in a manner that a portion thus removed corresponds to a region where the field oxide film is to be formed.

4. The manufacturing method of a semiconductor device according to claim 3, wherein, in the step of partially removing the insulating film, the silicon nitride film is removed after the field oxide film is formed.

5. The manufacturing method of a semiconductor device according to claim 3, wherein, in the step of forming the gate electrode, after the silicon nitride film is removed, a second silicon film is deposited over the top surface of the semiconductor layer, and a step height on the field oxide film is utilized as an alignment mark.

6. A semiconductor device comprising:
a semiconductor layer;
a field oxide film;
a gate electrode;
a gate oxide film;
a first drain diffusion layer of one conductivity type;
a second drain diffusion layer of the one conductivity type;
a back gate diffusion layer of an opposite conductivity type; and
a source diffusion layer of the one conductivity type,
wherein: the field oxide film is formed in a surface of the semiconductor layer;
the gate electrode is formed in a manner that one end thereof can be on the gate oxide film formed on the semiconductor layer;
the gate oxide film is sandwiched between the gate electrode and the semiconductor layer surface;
the other end of the gate electrode is formed on one end of the field oxide film;
the first drain diffusion layer is formed in a region facing the other end of the field oxide film; the second drain diffusion layer is formed in order that it can overlap the first drain diffusion layer;
the back gate diffusion layer is formed below the gate electrode; and
the source diffusion layer is formed in a manner that it extends below the one end side of the gate electrode.
